(19) United States
(12) Patent Application Publication
(10) Pub. No.: US 2017/0338816 A1
(43) Pub. Date: Nov. 23, 2017

(54) CAPACITIVE KEYBOARD

(71) Applicant: TOPRE CORPORATION, Tokyo (JP)

(72) Inventor: Shigeki Minezaki, Kanagawa (JP)

(73) Assignee: TOPRE CORPORATION, Tokyo (JP)

(21) Appl. No.: 15/527,096

(22) PCT Filed: Nov. 4, 2015
(86) PCT No.: PCT/JP2015/081672

§ 371 Date: May 16, 2017

(30) Foreign Application Priority Data
Nov. 17, 2014 (JP) 2014-232584

(51) Int. Cl. H03K 17/96; H03M 11/00; H03M 11/20

(52) U.S. Cl. CPC H03K 17/9622; H03M 11/20; H03M 11/003; H03K 2017/9613

(57) ABSTRACT

A capacitive keyboard that can detect a key that has been depressed and the depressed amount thereof with high accuracy is provided. The capacitive keyboard includes a drive circuit 11 that alternatively switches the voltage of each of drive lines M from an L-level to an H-level, a sensing circuit 12 that detects the voltage generated in each of sensing lines N, and a control circuit 15 that detects, on the basis of the voltage value detected by the sensing circuit 12, the key that has been operated and the operation amount of the operated key. The sensing circuit 12 includes a peak hold circuit 32 that holds the peak value of the voltage that is input from a sensing line N over a predetermined period and an A/D conversion circuit 33 that converts the voltage held by the peak hold circuit 32 into a multi-stage digital voltage value.

### TECHNICAL FIELD

The present invention relates to a capacitive keyboard including a plurality of capacitive keys arranged in a matrix.

### BACKGROUND ART

As a keyboard used for a personal computer and the like, a capacitive keyboard including a plurality of capacitive keys has been proposed and put into practical use. A capacitive keyboard includes a plurality of drive lines and a plurality of sensing lines that intersect the drive lines, and a capacitive key is arranged at each of the intersections of the drive lines and the sensing lines. Upon depressing of any one of the plurality of keys, the capacitance between two electrodes of the key is increased, and accordingly, current flows from a corresponding one of the drive lines through the depressed key to a corresponding one of the sensing lines. By detecting the current, the depressed key can be recognized (see, for example, PTL 1).

Now, a capacitive keyboard of the related art will be described below with reference to FIGS. 8 and 9. FIG. 8 illustrates the arrangement configuration of the capacitive keyboard of the related art, and FIG. 9 is an equivalent circuit diagram of the capacitive keyboard of the related art. As illustrated in FIG. 8, in the capacitive keyboard of the related art, a plurality of drive lines M (M-1, M-2, M-3 . . . ) and a plurality of sensing lines N (N-1, N-2, N-3 . . . ) are arranged to intersect with one another. Each of the drive lines M is connected to a drive circuit 101, and each of the sensing lines N is connected to a sensing circuit 102.

Keys 103 (103a, 103b, and the like) are arranged at intersections of the drive lines M and the sensing lines N. Upon depressing of any one of the keys 103, the capacitance at the intersection of a corresponding one of the drive lines M and a corresponding one of the sensing lines N can be changed. Specifically, upon depressing of any one of the keys 103, the capacitance is increased. Thus, keys are expressed by symbols of variable capacitors in the drawings.

The drive circuit 101 alternatively applies an H-level voltage to each of the drive lines M over a fixed period. Accordingly, for example, upon depressing of the key 103a illustrated in FIG. 8, if an H-level is set in the drive line M-4, current flows from the drive line M-4 through the sensing line N-5 to the sensing circuit 102. That is, current flows through the path indicated by arrows Y0 and Y1 in FIG. 8. Accordingly, while the drive line M-4 is set at the H-level by the drive circuit 101, on the basis of detection of the voltage of the sensing line N-5, the sensing circuit 102 can detect that the key 103a has been depressed.

However, if a key other than the key 103a is depressed as a result of erroneously or intentionally depressing a plurality of keys, for example, the sensing circuit 102 cannot detect the exact voltage in some cases. For example, while the key 103a is depressed, if the key 103b is further depressed, current that flows in the drive line M-4 is supplied through the sensing line N-5 to the sensing circuit 102 and through the drive line M-6 to the ground. That is, current flows through the path indicated by an arrow Y2 in FIG. 8.

This phenomenon will be described with reference to the equivalent circuit illustrated in FIG. 9. If only the key 103a is depressed, current that flows through a capacitor C101 flows via a resistor R2 to the ground. Thus, by measuring the voltage at a node P1 of the resistor R2, it is possible to detect that the key 103a has been depressed. At this time, if the key 103b is further depressed so that current flows through a capacitor C102, the voltage value detected by the sensing circuit 102 is lower than the voltage detected during a normal operation. Accordingly, the voltage value might not reach a threshold for determining whether or not the key has been depressed, and the detection might fail. If three or more keys are depressed at the same time, such detection failure may occur with a higher possibility.

Recently, there has been a demand for proposing a keyboard having a function of, in addition to detecting whether or not a key has been depressed, detecting the depressed amount of a key (stroke of a key). In addition, there is a demand for a keyboard to have a function that enables various input operations by depressing a number of keys at the same time. Although the technique disclosed in PTL 1 can detect whether or not a key has been depressed, it is difficult to detect the depressed amount of the key. In addition, if a plurality of keys are depressed at the same time, a problem arises in that the depressed amount of each key cannot be detected with high accuracy.

### CITATION LIST

### Patent Literature

PTL 1: Japanese Unexamined Patent Application Publication No. 62-144223

### SUMMARY OF INVENTION

### Technical Problem

As described above, the capacitive keyboard of the related art can detect whether or not a key has been depressed, but cannot detect the depressed amount thereof, and a demand for detecting the depressed amount of a key with high accuracy has been increased.

The present invention has been made in order to solve such a problem of the related art, and an object of the present invention is to provide a capacitive keyboard that can detect a key that has been depressed and the depressed amount thereof with high accuracy.

The object of the present invention is to further provide a capacitive keyboard that can detect, even if a plurality of keys are depressed, the depressed amounts of all of the keys at the same time.

### Solution to Problem

To achieve the above object, the invention of this application includes a plurality of drive lines and a plurality of sensing lines that intersect the drive lines and includes keys provided at intersections of the drive lines and the sensing lines, each of the keys including an operation component and an electrode unit including a pair of electrodes connected to a corresponding one of the drive lines and a corresponding one of the sensing lines, capacitance between the electrodes being changed in accordance with a depressed amount of the operation component; a drive circuit that is connected to each of the drive lines and that alternatively switches a voltage of each of the drive lines from a low level to a high level; a sensing circuit that is connected to the sensing lines and that detects a voltage generated in each of the sensing lines; and an operation detecting unit that detects, on the basis of a voltage value detected by the sensing circuit, one of the keys that has been operated and an operation amount of the operated key, wherein the sensing circuit includes a peak hold unit that holds a peak value of the voltage that is input from a sensing line over a predetermined period and an A/D conversion unit that converts the voltage held by the peak hold unit into a multi-stage digital voltage value.

### Advantageous Effects of Invention

In the capacitive keyboard according to the present invention, if an operator presses a key, the voltage that is generated in a sensing line in accordance with the depressed amount of the key is detected by a sensing circuit, and this voltage is held by a peak hold unit. Then, the voltage held by the peak hold unit is converted into a multi-stage digital voltage value, and on the basis of the voltage value, the key that has been depressed and the depressed amount thereof are detected. Accordingly, it becomes possible to detect the key that has been depressed by the operator and the depressed amount thereof with high accuracy.

### BRIEF DESCRIPTION OF DRAWINGS

FIG. 1 is a circuit diagram of a capacitive keyboard according to an embodiment of the present invention.

FIG. 2 is an exploded perspective view illustrating a detailed configuration of a key used for the capacitive keyboard according to the embodiment of the present invention.

FIG. 3 schematically illustrates the relationship between two electrodes and a coil spring in a key used for the capacitive keyboard according to the embodiment of the present invention.

FIG. 4 is a block diagram illustrating a detailed configuration of a sensing circuit of the capacitive keyboard according to the embodiment of the present invention.

FIG. 5 illustrates current that flows when a key Ky-45 of the capacitive keyboard according to the embodiment of the present invention is depressed.

FIG. 6 is an equivalent circuit diagram illustrating current that flows when a desired key of the capacitive keyboard according to the embodiment of the present invention is depressed.

FIG. 7 is a timing chart illustrating changes in each signal when the depressed amount of a desired key of the capacitive keyboard according to the embodiment of the present invention is small and large.

FIG. 8 is a circuit diagram of a capacitive keyboard of the related art.

FIG. 9 is an equivalent circuit diagram of the capacitive keyboard of the related art.

### DESCRIPTION OF EMBODIMENTS

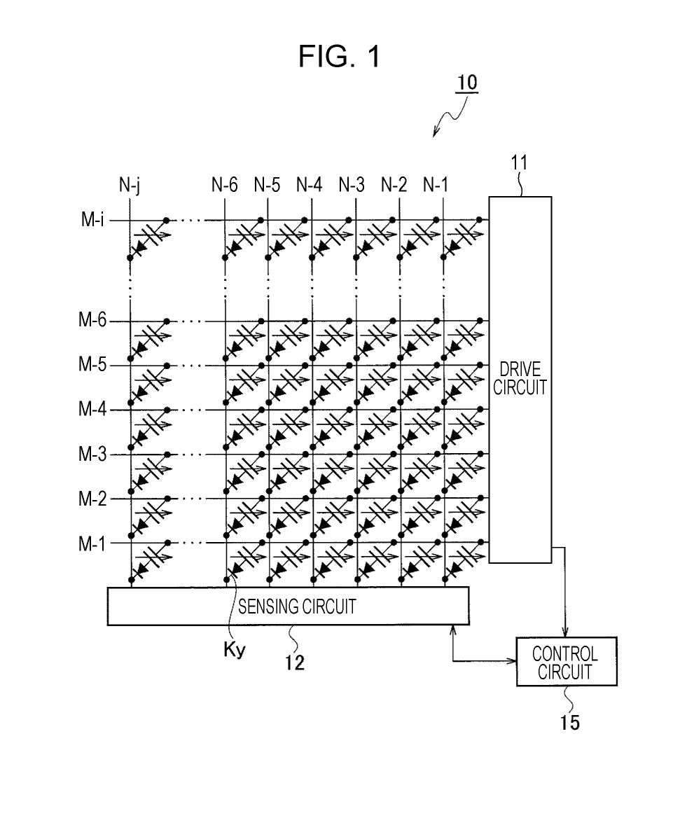

Now, an embodiment of the present invention will be described below with reference to the drawings. FIG. 1 schematically illustrates the configuration of a capacitive keyboard device according to the embodiment of the present invention. As illustrated in FIG. 1, in a capacitive keyboard 10 according to this embodiment, a plurality (for example, the number being i) of drive lines M (M-1, M-2, M-3, . . . , M-i) and a plurality (for example, the number being j) of sensing lines N (N-1, N-2, N-3, . . . , N-j) are arranged to intersect (cross) one another. Note that in the following description, unless indicating a specific drive line, the drive lines are denoted by symbol “M”, and if indicating a specific drive line, the individual drive lines are denoted by a suffix such as “M-1”. Similarly for the sensing lines, unless indicating a specific sensing line, the sensing lines are denoted by symbol “N”, and if indicating a specific sensing line, the individual sensing lines are denoted by a suffix such as “N-1”.

As illustrated in FIG. 1, the drive lines M are connected to a drive circuit 11, and the sensing lines N are connected to a sensing circuit 12. The drive circuit 11 and the sensing circuit 12 are connected to a control circuit 15, and the control circuit 15 controls driving of the drive circuit 11 and the sensing circuit 12.

The drive lines M and the sensing lines N are connected to one another at the respective intersections with keys Ky, and at a normal time (when keys Ky are not depressed), the lines M and N are not electrically continuous at the intersections. As will be described later, each of the keys Ky includes a series-connection circuit of a variable capacitor and a diode. Thus, each of the keys Ky is expressed by a symbol of a variable capacitor and a symbol of a diode.

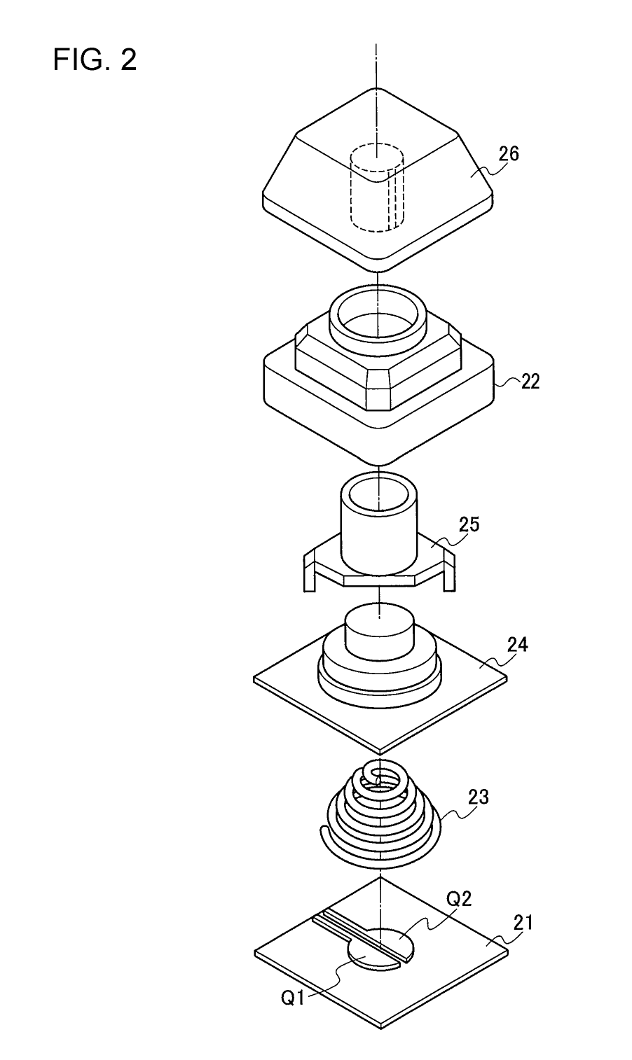

As illustrated in FIG. 2, each of the keys Ky includes a substrate 21 having a pair of electrodes Q1 and Q2 (electrode unit) and a housing 22. Between the substrate 21 and the housing 22, a circular conical coil spring 23, a flexible rubber 24, and a plunger 25 are provided. Note that the electrodes Q1 and Q2 and the coil spring 23 are electrically insulated from one another with an insulating layer, which is not illustrated, and thereby forming a capacitor. Furthermore, a key top 26 (operation component) is provided above the housing 22. Upon an operator depressing the key top 26, the coil spring 23 is depressed, and thereby the capacitance between the electrodes Q1 and Q2 is changed. That is, each of the keys Ky is configured to cause the capacitance between the electrodes Q1 and Q2 to be increased in accordance with the depressed amount of the key top 26.

Note that in the following description, unless indicating a specific key, the plurality of keys Ky are denoted by symbol “Ky”, and if indicating a specific key, the plurality of keys Ky are denoted by a number of a drive line M and a number of a sensing line N forming an intersection. For example, a key provided at the intersection of the drive line M-4 and the sensing line N-5 is denoted by symbol “Ky-45”.

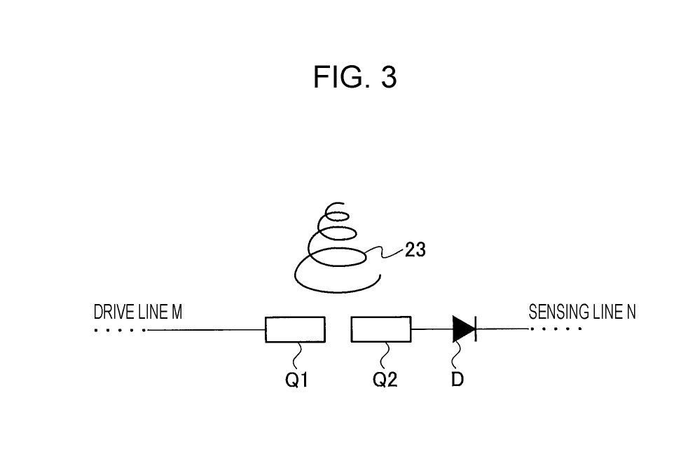

In addition, the electrode Q1 (first electrode), which is one of the two electrodes Q1 and Q2 provided in each of the above-described keys Ky, is connected to a drive line M, and the electrode Q2 (second electrode), which is the other, is connected to a sensing line N through a diode D (rectifier). Specifically, as schematically illustrated in FIG. 3, the electrode Q1 and the electrode Q2 are arranged to face each other with a fixed distance therebetween, the electrode Q1 is connected to the drive line M, the electrode Q2 is connected to an anode of the diode D, and a cathode of the diode D is connected to the sensing line N. That is, the diode D is provided to have a forward direction that is in the direction from the drive line M to the sensing line N. In addition, the diode D is arranged between the electrodes Q1 and Q2 (pair of electrodes) and the sensing line N.

The capacitance between the electrodes Q1 and Q2 is changed in accordance with the expansion and contraction status (i.e., depressed amount of the key top 26 illustrated in FIG. 2) of the coil spring 23 provided between the two electrodes Q1 and Q2. Thus, current that flows from the electrode Q1 to the electrode Q2 is changed accordingly.

On the basis of a control instruction that is output from the control circuit 15, the drive circuit 11 illustrated in FIG. 1 performs control to alternatively apply an H-level (high level) voltage to each of the drive lines M (M-1 to M-i) over a fixed period. Specifically, the voltage of each of the drive lines M in the order of M-1, M-2, . . . , M-i, M-1 . . . is set at an H-level. The voltage of other drive lines M is set at an L-level (low level). Note that the order for applying the voltage is not limited to the above order, and the voltage may alternatively be set at an H-level in the drive lines M in any order in a fixed cycle.

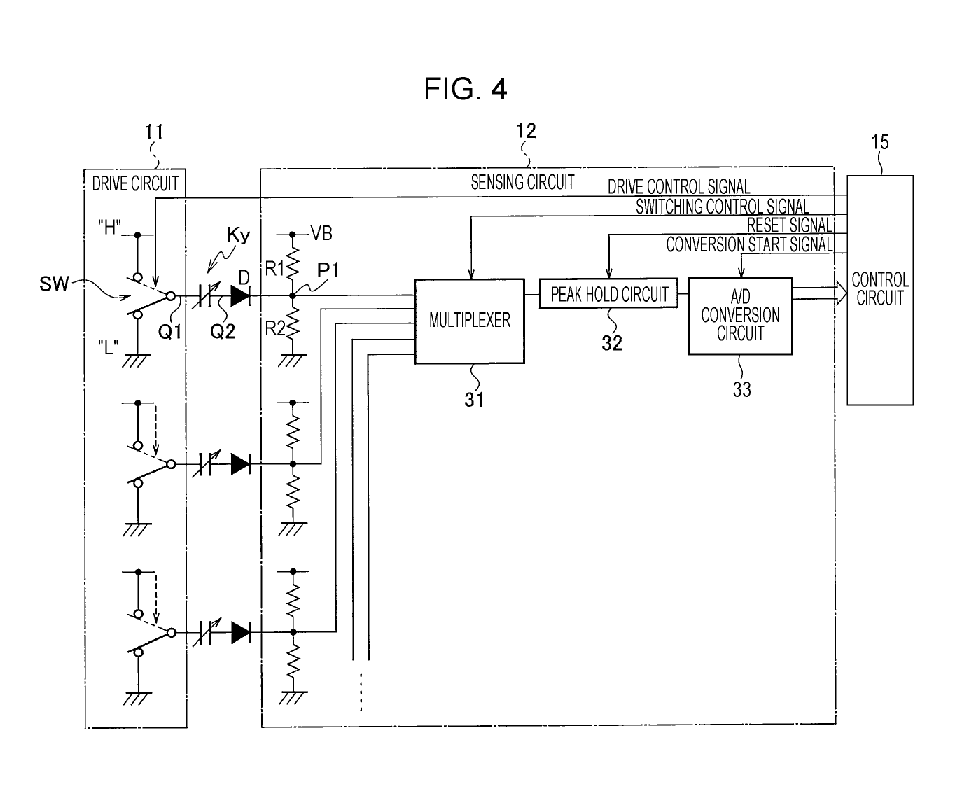

The sensing circuit 12 detects the voltage in accordance with current that flows in each of the sensing lines N. Now, details of the sensing circuit 12 will be described below with reference to the block diagram illustrated in FIG. 4. FIG. 4 is a block diagram illustrating the sensing circuit 12 and the keys Ky connected to the sensing circuit 12. As described above, each of the drive lines M is switched to be at an H-level and an L-level under control of the drive circuit 11, and thus, the switching is expressed by a switch SW and an arrow indicating a drive control signal for convenience sake. That is, if an instruction for setting a drive line M at an H-level is supplied on the basis of a drive control signal that is output from the control circuit 15, the switch SW is switched from “L” to “H”, and an H-level voltage is applied to the keys Ky.

In addition, as illustrated in FIG. 4, the sensing circuit 12 includes a series-connection circuit of resistors R1 and R2. A node P1 between the resistors R1 and R2 is connected to an output terminal (i.e., cathode of the diode D) of a key Ky. A terminal of the resistor R1 is connected to a terminal for a power supply voltage VB, and a terminal of the resistor R2 is connected to the ground. This series-connection circuit is provided for each of the sensing lines N, and the node P1 is connected to a multiplexer 31. The resistors R1 and R2 have equal resistances. Thus, the voltage at the node P1 is the intermediate voltage value between the power supply voltage VB that is supplied to the sensing circuit 12 and the ground voltage.

The multiplexer 31 alternatively switches the voltage (voltage generated across the resistor R2, i.e., voltage at the node P1) in accordance with current that flows in the sensing lines N via the keys Ky (Ky-11 to Ky-ij) in a fixed cycle by using an analog switch and outputs the voltage to a peak hold circuit 32 (peak hold unit).

The peak hold circuit 32 detects the peak value of the voltage generated at the node P1 and holds the detected peak value. Upon reception of a reset signal from the control circuit 15, the peak hold circuit 32 resets the held peak value.

Upon reception of a conversion start signal from the control circuit 15, an A/D conversion circuit 33 converts the voltage peak value that has been held by the peak hold circuit 32 into a digital value and outputs the digital data to the control circuit 15.

Accordingly, if the switch SW is switched from “off” to “on” (i.e., voltage of drive line M is switched from L-level to H-level), upon an operator depressing a key Ky, the capacitance between the electrodes Q1 and Q2 is increased, and current flows. Accordingly, the voltage at the node P1 is increased. This voltage is temporarily held by the peak hold circuit 32 and converted into a digital value by the A/D conversion circuit 33 to be output to the control circuit 15. In the control circuit 15, by reading the digital voltage value, the depressed amount of the depressed key Ky can be detected, and on the basis of the depressed amount, whether or not the key has been depressed can be determined. Furthermore, on the basis of temporal changes in the depressed amount, the depressing speed can be detected.

The information about the depressing of these keys Ky is converted into key codes by the control circuit 15 and transmitted through an interface (omitted from illustration) to a host computer (omitted from illustration). That is, the control circuit 15 has a function of an operation detecting unit that detects, on the basis of the voltage detected by the sensing circuit 12, an operated key Ky and the operation amount thereof.

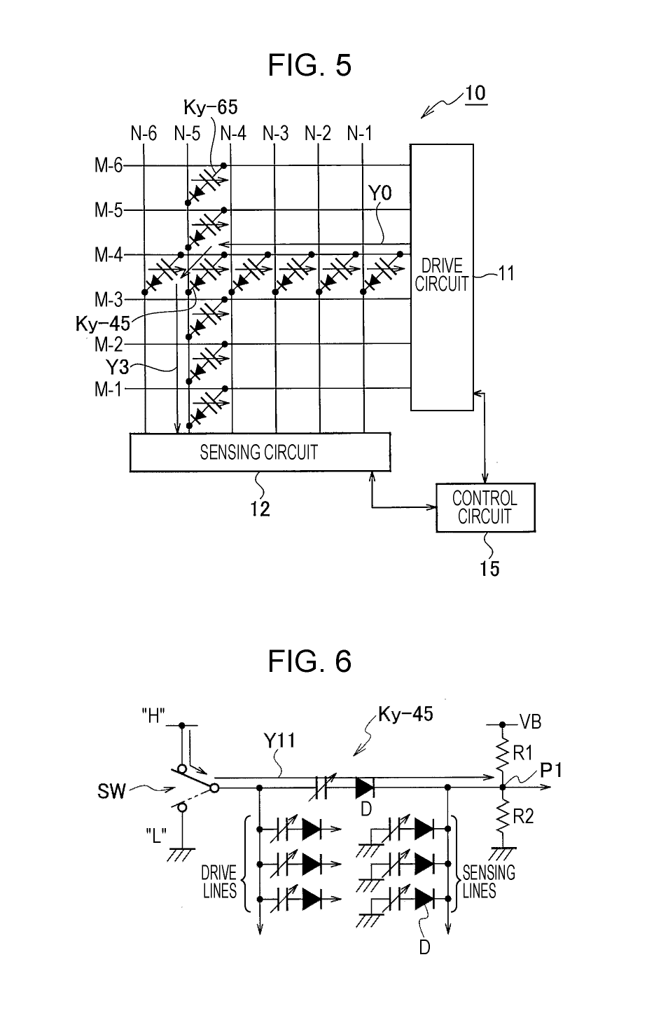

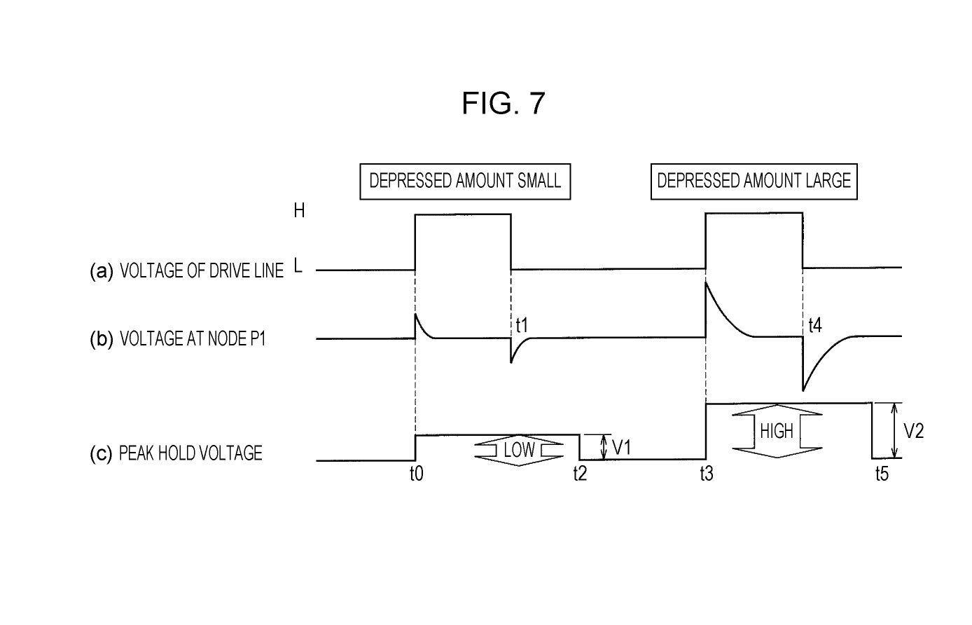

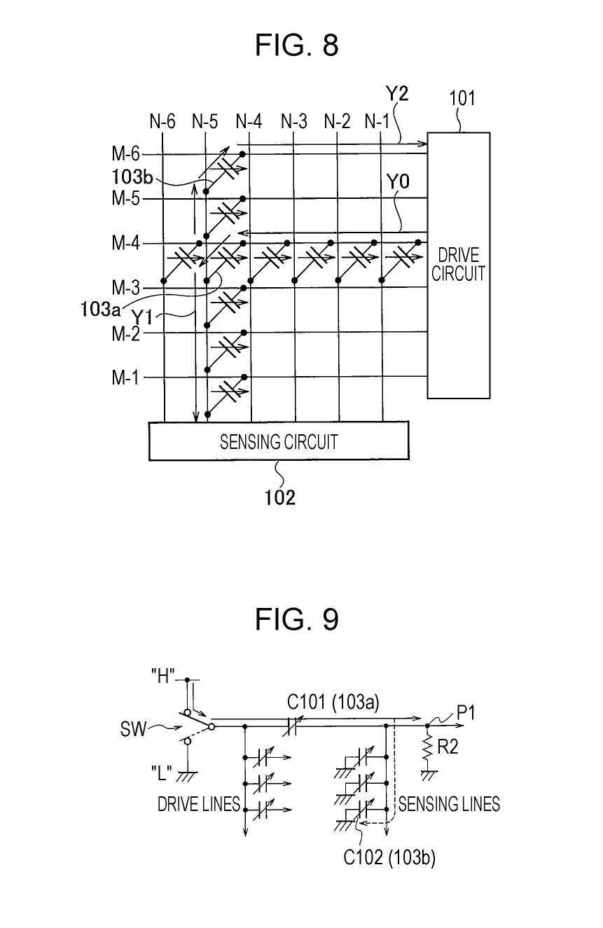

Next, operations of the thus configured capacitive keyboard 10 according to this embodiment will be described with reference to circuit diagrams illustrated in FIGS. 5 and 6. FIG. 5 illustrates current that flows when a key Ky-45 among the plurality of keys Ky is depressed, and FIG. 6 is an equivalent circuit diagram of this case. In addition, FIG. 7 is a timing chart illustrating the waveform of each signal. Note that FIG. 5 illustrates only some of the keys Ky connected to the drive line M-4 and the sensing line N-5, and the other keys Ky are omitted from illustration for simplicity.

As illustrated in FIG. 5, upon depressing of the key Ky-45, the key top 26 illustrated in FIG. 2 is depressed, and thereby the coil spring 23 is depressed. Accordingly, the capacitance between the electrodes Q1 and Q2 is increased. In addition, since the drive circuit 11 controls the voltage of each of the drive lines M to be sequentially switched from an L-level to an H-level, when the drive line M-4 is set at the H-level, current flows through the electrodes Q1 and Q2 of the key Ky-45. That is, current flows through a path from the drive line M-4, the key Ky-45, and the sensing line N-5 (path indicated by arrows Y0 and Y3 in the drawing), and the voltage at the node P1 (see FIG. 6) is increased. This voltage is supplied through the multiplexer 31 to the peak hold circuit 32. Thus, the voltage peak value is held, and in addition, is converted into a multi-stage digital value by the A/D conversion circuit 33. Then, the voltage is output to the control circuit 15.

The above operations will be described with reference to the timing chart illustrated in FIG. 7. As illustrated in FIG. 7(a), if the drive line M-4 is switched from an L-level to an H-level at time t0, and upon depressing of the key Ky-45 with a small depressed amount, the capacitance in the key Ky-45 is higher than that at a normal time (when the key is not depressed). Accordingly, as illustrated in FIG. 7(b), current flows in the key Ky-45 at the time of switching from L to H (time t0) and at the time of switching from H to L (time t1), and the voltage at the node P1 is changed. Specifically, the voltage is increased at time t0 and is decreased at time t1. In addition, since the peak hold circuit 32 (see FIG. 4) holds this voltage (voltage V1), as illustrated in FIG. 7(c), the voltage peak value is held. That is, it is recognized that the key Ky-45 has been depressed with a small depressed amount. Then, upon reception of a reset signal at time t2, the held peak value is reset.

On the other hand, if the drive line M-4 is switched from an L-level to an H-level at time t3, upon depressing of the key Ky-45 with a large depressed amount, as illustrated in FIG. 7(b), current flows in the key Ky-45 at times t3 and t4, and the voltage at the node P1 is increased and decreased. In this case, since the depressed amount of the key is large, the capacitance between the electrodes Q1 and Q2 is higher than that at time t0. Accordingly, current that flows in the key Ky-45 is increased, and the voltage (voltage V2) generated at the node P1 is increased. That is, V2>V1 is satisfied. Then, the voltage peak value is held and converted into a digital value to be output to the control circuit 15.

Through the above processing, the control circuit 15 can recognize that the key Ky-45 has been depressed and the depressed amount thereof. Specifically, at time t0 illustrated in FIG. 7, it is possible to recognize that the key Ky-45 has been depressed with a small depressed amount, and at time t3, it is possible to recognize that the key Ky-45 has been depressed with a large depressed amount. If the depressed amount and the period taken for a depressing operation are measured, the depressing speed can be calculated.

Then, the control circuit 15 converts the information about the depressing of the key Ky-45 into a key code and transmits the information to a host computer. Thus, control can be performed on the basis of the information about the depressing of the key Ky-45.

Note that although FIG. 7 illustrates the case of two stages: when the depressed amount is small and large, the capacitance between the electrodes Q1 and Q2 is continuously changed in accordance with the depressed amount of a key Ky, detection can be performed in a plurality of ways in accordance with the changed amount. For example, if the depressed amount of a key Ky is divided into five stages, and if the voltage value is detected in five stages on the basis of the voltage generated at the node P1, the depressed amount of the key Ky can be recognized in five stages (multi-stage digital value).

In the above manner, by sequentially applying an H-level voltage to each of the drive lines M and sequentially switching each of the sensing lines N by using the multiplexer 31, it is possible to detect whether or not each of the keys Ky has been depressed, the depressed amount thereof, and the depressing speed. Furthermore, information about all of the keys Ky can be transmitted to a host computer.

Next, operations in a case where an unexpected key Ky-65 is further erroneously depressed when the desired key Ky-45 is depressed will be described. As illustrated in FIG. 5, while the key Ky-45 is depressed, if the key Ky-65 connected to the same sensing line N-5 as the key Ky-45 is depressed, the capacitance between the electrodes Q1 and Q1 provided in the key Ky-65 is increased. However, since the diode D having the forward direction in the direction from the drive line M-6 to the sensing line N-5 is provided in the key Ky-65, current that flows from the key Ky-45 to the sensing line N-5 does not flow in the key Ky-65.

That is, as illustrated in FIG. 6, when the key Ky-45 is depressed, as indicated by an arrow Y11 in the drawing, current flows through the diode D to the node P1. At this time, since the diode D is provided in each of the other keys Ky connected to the sensing line N-5, even if another key Ky is depressed, current does not flow in this key Ky.

In a device of the related art in which the diode D is not provided in a key Ky, part of current that flows in the sensing line N-5 flows through the key Ky-65 to the drive line M-6, and further to the ground. As a result, a problem arises in that current that flows from the key Ky-45 through the sensing line N-5 to the sensing circuit 12 is decreased, thereby decreasing the detection accuracy. However, in this embodiment, since the diode D is provided in each of the keys Ky, substantially all of the current that flows through the key Ky-45 flows to the sensing circuit 12. Accordingly, unlike in the related art, false detection of another key instead of the correct key Ky-45 as a result of erroneously depressing two keys Ky at the same time and a decrease in the accuracy of detecting the depressed amount can be avoided.

Next, operations performed if two desired keys Ky are intentionally depressed at the same time will be described. For example, taking a keyboard for a personal computer as an example, the following case is considered in which “A” is depressed while depressing the “Sift” key in order to input a lowercase “a”. The case in which the key Ky-45 and the key Ky-65 are depressed at the same time as an example of the two keys will be described.

If the two keys Ky-45 and Ky-65 are depressed at the same time, as described above with reference to FIG. 5, if the drive line M-4 is set at an H-level, current does not flow in the key Ky-65 because the diode D is provided. Accordingly, depressing of the key Ky-45 and the depressed amount thereof are detected with high accuracy. Then, if the drive control signal that is output from the drive circuit 11 is switched, and if the drive line M-6 is set at an H-level, current flows in the key Ky-65. At this time, although the drive line M-4 is at the L-level, current does not flow in the key Ky-45 because the diode D is provided. Accordingly, depressing of the key Ky-65 and the depressed amount thereof are detected with high accuracy.

From the above description, depressing of the two keys Ky-45 and Ky-65 is detected with high accuracy, and as a result, it is recognized that the two keys have been depressed at the same time. Furthermore, even if three or more keys Ky are depressed at the same time, it is similarly recognized that the three or more keys have been depressed at the same time.

In the above manner, the capacitive keyboard 10 according to this embodiment includes the peak hold circuit 32 in the sensing circuit 12, which holds the voltage peak value generated at the node P1. In addition, the voltage held by the peak hold circuit 32 is converted into a multi-stage digital value by the A/D conversion circuit 33. Thus, the voltage generated in accordance with current that flows in the depressed key Ky can be detected with high accuracy, and the depressed key Ky, the depressed amount thereof, and the depressing speed can be detected with high accuracy. Accordingly, it becomes possible to input an instruction with fine movement or the like by using an application program based on the depressed amount and the depressing speed of a key Ky, and thereby a new input device can be provided in addition to the simple on-and-off function of a keyboard of the related art. For example, it becomes possible to apply this technology to new game software or the like so as to input an instruction about a detailed operation command through the keyboard of the present invention.

In addition, in the capacitive keyboard 10 according to this embodiment, the diode D is provided in each of the plurality of keys Ky. Thus, even if a plurality of keys Ky are depressed at the same time, current that flows in a desired key Ky can be prevented from flowing in another key, and the depressed amount (length of depressing stroke) of the key Ky can be detected with high accuracy. Accordingly, if an input operation is detected stepwise in accordance with the depressed amount of the key Ky, it is possible to detect each input operation with high accuracy. If this technology is applied to the above-described game software, it becomes possible to input an instruction about a plurality of operation commands at the same time through the keyboard of the present invention.

In addition, since the configuration is such that the diode D (rectifier) is provided between the electrode Q2 and a sensing line N, current can be prevented from flowing between the electrodes Q1 and Q2. Even if an unexpected key Ky is depressed, it is possible to more reliably prevent current from flowing in this key Ky.

Furthermore, since the resistances of the two resistors R1 and R2 illustrated in FIG. 4 are equal to each other and the power supply voltage VB is divided to generate the voltage at the node P1, the voltage generated by current that is supplied from the sensing line N can be stabilized. Accordingly, it becomes possible to stably detect the information about the depressing of the key Ky.

Although the capacitive keyboard of the present invention has been described above on the basis of the illustrated embodiment, the present invention is not limited to the above embodiment, and the configuration of each unit can be replaced by a given configuration having the same or similar functions.

For example, although the above-described embodiment has illustrated the configuration in which the keys Ky are arranged at the respective intersections of the drive lines M and the sensing lines N, the present invention is not limited to this configuration, and keys may be absent in some of the intersections. In addition, the number of the drive lines M may be equal to the number of the sensing lines N. That is, i=j may be satisfied.

In addition, although the above-described embodiment has illustrated the configuration (see FIG. 3) in which the diode D is provided between the electrodes Q1 and Q2 and a sensing line N, the diode D may be provided between the electrodes Q1 and Q2 and a drive line M. Furthermore, although the above-described embodiment has illustrated the example in which the diode is used as a rectifier, the present invention is not limited to this example, and another rectifier may be used. For example, a PN conjunction part of a bipolar transistor or a thyristor may be used as a rectifier.

Furthermore, although the above-described embodiment has illustrated an example in which the resistances of the two resistors R1 and R2 provided in the sensing circuit 12 are equal to each other, the present invention is not limited to this example, and different resistances may be used.

### INDUSTRIAL APPLICABILITY

According to the present invention, it is possible to provide a capacitive keyboard that can detect a key that has been depressed and the depressed amount thereof with high accuracy.

### REFERENCE SIGNS LIST

10 capacitive keyboard
11 drive circuit
12 sensing circuit
15 control circuit
21 substrate
22 housing
23 coil spring
24 rubber
25 plunger
26 key top
31 multiplexer
32 peak hold circuit
33 A/D conversion circuit
Q1, Q2 electrode
R1 resistor
R2 resistor
SW switch

1. A capacitive keyboard comprising a plurality of drive lines and a plurality of sensing lines that intersect the drive lines, the keyboard comprising: keys provided at intersections of the drive lines and the sensing lines, each of the keys including an operation component and an electrode unit including a pair of electrodes connected to a corresponding one of the drive lines and a corresponding one of the sensing lines, capacitance between the electrodes being changed in accordance with a depressed amount of the operation component; a drive circuit that is connected to each of the drive lines and that alternatively switches a voltage of each of the drive lines from a low level to a high level; a sensing circuit that is connected to the sensing lines and that detects a voltage generated in each of the sensing lines; and an operation detecting unit that detects, on the basis of a voltage value detected by the sensing circuit, one of the keys that has been operated and an operation amount of the operated key, wherein the sensing circuit includes a peak hold unit that holds a peak value of the voltage that is input from a sensing line over a predetermined period and an A/D conversion unit that converts the voltage held by the peak hold unit into a multi-stage digital voltage value.

2. The capacitive keyboard according to claim 1, wherein the electrode unit is composed of a first electrode and a second electrode that is arranged to be close to the first electrode, the first electrode is connected to a corresponding one of the drive lines, the second electrode is connected to a corresponding one of the sensing lines, and the key includes a rectifier whose forward direction is in a direction from a corresponding one of the drive lines to a corresponding one of the sensing lines.

3. The capacitive keyboard according to claim 2, wherein the rectifier is arranged between the pair of electrodes and the sensing line.

4. The capacitive keyboard according to claim 1, wherein the voltage of each of the sensing lines is held at an intermediate value between a power supply voltage to be supplied to the sensing circuit and a ground voltage.
